(19) United States
(12) Patent Application Publication
(10) Pub. No.: US 2025/0374553 A1
(43) Pub. Date: Dec. 4, 2025

(54) SEMICONDUCTOR MEMORY DEVICE HAVING A MAGNET TUNNELING JUNCTION

(71) Applicant: SK hynix Inc., Icheon-si (KR)

(72) Inventors: Jin Won JUNG, Icheon-si (KR); Jung Hyeok KWAK, Icheon-si (KR); Ku Youl JUNG, Icheon-si (KR); Tae Yup KIM, Icheon-si (KR)

(21) Appl. No.: 19/094,391

(22) Filed: Mar. 28, 2025

(30) Foreign Application Priority Data
May 31, 2024 (KR) 10-2024-0071538

(51) Int. Cl. H10B 61/00

(52) U.S. Cl. CPC H10B 61/10

(57) ABSTRACT

A semiconductor device includes lower electrode; a selection element layer over the lower electrode; a middle electrode over the selection element layer; a carbon blocking element layer over the middle electrode; a variable resistance element layer over the carbon blocking element layer; and an upper electrode over the variable resistance element layer. The carbon blocking element layer includes a carbon absorption layer to absorb carbon atoms and a carbon barrier layer to block diffusion of the carbon atoms.

### PRIORITY CLAIM AND CROSS-REFERENCE TO RELATED APPLICATIONS

This patent document claims the priority and benefits of Korean Patent Application No. 10-2024-0071538, filed on May 31, 2024, which is incorporated herein by reference in its entirety.

### TECHNICAL FIELD

The present disclosure relates to a semiconductor memory device including a magnetic tunneling junction (MTJ).

### BACKGROUND

Nonvolatile memory devices using magnetization properties have been proposed.

### SUMMARY

In accordance with an embodiment of the present disclosure, a semiconductor device includes a lower electrode; a selection element layer over the lower electrode and configured to exhibit different electrical conducting characteristics in response to an applied voltage with respect to a threshold voltage; a middle electrode over the selection element layer such that the selection element layer is between the lower electrode and the middle electrode; a carbon blocking element layer over the middle electrode; a variable resistance element layer over the carbon blocking element layer; and an upper electrode over the variable resistance element layer such that the variable resistance element layer and carbon blocking element layer are between the upper electrode and the middle electrode. The carbon blocking element layer includes a carbon absorption layer configured to absorb carbon atoms diffusing or moving from the middle electrode toward the variable resistance element and a carbon barrier layer configured to block a diffusion of the carbon atoms.

In accordance with another embodiment of the present disclosure, a semiconductor device includes a lower interconnection; a lower electrode over the lower interconnection; a selection element layer over the lower electrode; a carbon layer over the selection element layer; a carbon diffusion blocking element layer over the carbon layer; a variable resistance element layer over the carbon diffusion blocking layer; an upper electrode over variable resistance element layer; and an upper interconnection over the upper electrode. The carbon diffusion blocking element layer includes a carbon absorption layer configured to absorb carbon atoms that diffuse or move toward the variable resistance element layer; a carbon diffusion barrier layer; and a carbon diffusion blocking layer and a carbon diffusion blocking layer that include materials different from each other, the carbon diffusion barrier layer and the carbon diffusion blocking layer configured to interfere or block a diffusion or a movement of the carbon atoms.

### BRIEF DESCRIPTION OF THE DRAWINGS

FIG. 1 is a perspective view schematically illustrating a cross-point cell array of memory devices according to an embodiment of the present disclosure.

FIG. 2 is a longitudinal cross-sectional view taken along the line I-I′ of FIG. 1.

FIGS. 3A to 3G are longitudinal cross-sectional views schematically illustrating carbon blocking element layers according to embodiments of the present disclosure.

FIG. 4 is a diagram illustrating a variable resistance element layer according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

An embodiment of the present disclosure provides a semiconductor memory device having a magnetic tunneling junction (MTJ).

An embodiment of the present disclosure provides a semiconductor memory device having a carbon electrode.

An embodiment of the present disclosure provides a semiconductor memory device including a carbon blocking element layer blocking carbon diffusion.

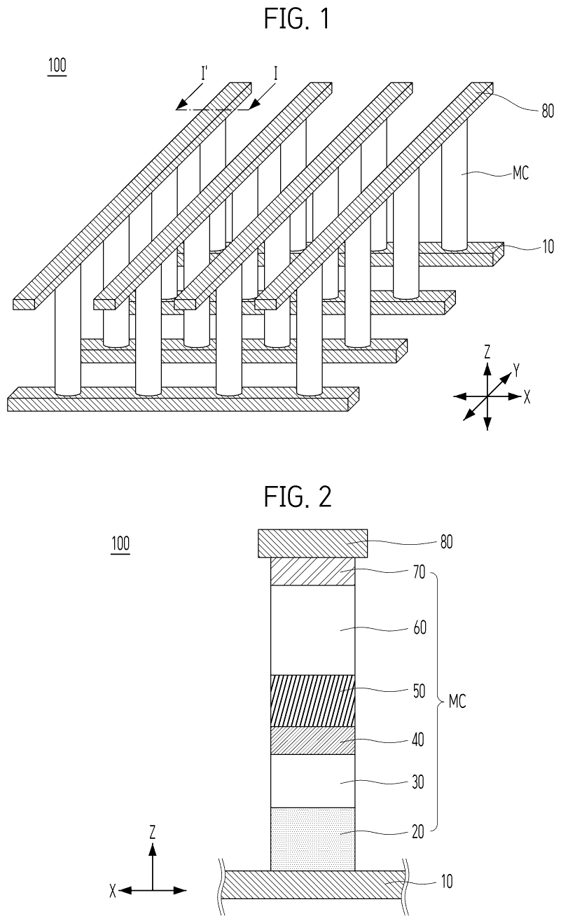

FIG. 1 is a perspective view schematically illustrating a cross-point cell array 100 of memory devices according to an embodiment of the present disclosure, and FIG. 2 is a longitudinal cross-sectional view taken along the line I-I′ of FIG. 1.

Referring to FIGS. 1 and 2, a cross-point cell array 100 of a memory device according to an embodiment of the present disclosure may include lower lines 10, upper lines 80, and memory cells MC between the lower lines 10 and the upper lines 80. The lower lines 10 may extend in parallel with each other in a first horizontal direction X, and the upper lines 80 may extend in parallel with each other in a second horizontal direction Y. The first horizontal direction X and the second horizontal direction Y may be perpendicular to each other. For example, in a top view, the lower lines 10 and the upper lines 80 may intersect to each other. The memory cells MC may be disposed at intersections between the lower lines 10 and the upper lines 80.

Each of the memory cells MC may have a cylindrical pillar shape extending in a vertical direction Z. The vertical direction Z may be perpendicular to the first horizontal direction X and the second horizontal direction Y, respectively.

Referring to FIG. 2, the memory cell MC according to an embodiment of the present disclosure may include a lower electrode 20, a selection element layer 30, a middle electrode 40, a carbon blocking element layer 50, a variable resistance element layer 60, and an upper electrode 70 stacked in the vertical direction Z.

In some implementations, the lower line 10 may correspond to a word line. In another embodiment, the lower line 10 may correspond to a bit line. The lower line 10 may include a conductor, e.g., a metal or a metal compound. For example, the lower line 10 may include a metal such as tungsten (W), one of metal compounds such as titanium (Ti) and titanium nitride (TiN), or a combination thereof.

The lower electrode 20 may be disposed on the lower line 10 to have a pillar shape. The lower electrode 20 may receive a voltage or current from the lower line 10 and provide the voltage or current to the selection element layer 30.

For example, the lower electrode 20 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or a combination thereof.

The selection element layer 30 may be disposed on the lower electrode 20 to have a pillar shape or a pad shape. The selection element layer 30 may exhibit two different electrical conducting states: a first electrical non-conducting state in which a current is blocked or hardly flows in the selector element layer 30 when the magnitude of the voltage supplied to the selector element layer 30 is less than a predetermined threshold voltage, and a second electrical conducting state in which the current rapidly flows through the selector element layer 30 at a voltage equal to or higher than the threshold voltage. The selection element layer 30 may have the second electrical conducting state with the conductivity created by an electric field generated between the lower electrode 10 and the middle electrode 40. For example, a channel due to the electric field may be formed in the selection element layer 30. When the electric field is less than a threshold voltage or a threshold current, the selection element layer 30 may have non-conductor characteristics corresponding to the first electrical non-conducting state. When the electric field is greater than or equal to the threshold voltage or the threshold current, the selection element layer 30 may have conductor characteristics corresponding to the second electrical conducting state. Therefore, the applied voltage across the selection element layer 30 can be used to selectively switch the selection element layer 30 between the first electrical non-conducting state and the second electrical conducting state to selectively control the electrical connection to the memory layer 70 within each memory cell MC. The selection element layer 30 may include at least one of metal insulator transition (MIT) materials such as NbO₂, TiO₂, VO₂, WO₂, or etc., mixed ion-electron conducting (MIEC) materials such as ZrO₂(Y₂O₃), Bi₂O₃—BaO, (La₂O₃)ₓ(CeO₂)₁₋ₓ, and ovonic threshold switching (OTS) materials including chalcogenide materials such as Ge₂Sb₂Te₅, As₂Te₃, As₂Se₃, or etc. In another embodiment, the selection element layer 30 may include a dopant-doped insulating layer. For example, the selection element layer 30 is a dopant-doped silicon oxide, a dopant-doped titanium oxide, a dopant-doped aluminum oxide, a dopant-doped tungsten oxide, a dopant-doped hafnium oxide, a dopant-doped tantalum oxide, a dopant-doped niobium oxide, a dopant-doped silicon nitride, a dopant-doped titanium nitride, a dopant-doped aluminum nitride, a dopant-doped tungsten nitride, a dopant-doped hafnium nitride, a dopant-doped tantalum nitride, a dopant-doped niobium nitride, a dopant-doped silicon oxynitride, a dopant-doped titanium oxynitride, a dopant-doped aluminum oxynitride, a dopant-doped tungsten oxynitride, a dopant-doped hafnium oxynitride, a dopant-doped hafnium oxynitride, a dopant-doped niobium oxynitride, or a combination thereof. The dopant may include at least one of boron (B), nitrogen (N), carbon (C), phosphorus (P), arsenic (As), aluminum (Al), silicon (Si), or germanium (Ge). In an embodiment, the selection element layer 30 may include silicon oxide (SiO2) doped with at least one of arsenic (As) or germanium (Ge). In the embodiment, the selection element layer 30 may include silicon oxide (SiO2) doped with arsenic (As).

The middle electrode 40 may be disposed on the selection element layer 30 to have a pillar shape or a pad shape. The middle electrode 40 may include a carbon (C) layer. In another embodiment, the middle electrode 40 may include a conductor containing carbon. In another embodiment, the middle electrode 40 may include a carbon structure layer such as graphene layers.

The carbon blocking element layer 50 may be disposed on the middle electrode 40 to have a pillar shape or a pad shape. The carbon blocking element layer 50 may block diffusion or moving of carbon atoms or carbon ions from the middle electrode 40 to the variable resistance element layer 60. Thus, the carbon blocking element layer 50 may include carbon diffusion blocking layers. The carbon blocking element layer 50 will be described in detail with reference to other drawings.

In an embodiment, the memory cell MC may further include a barrier metal layer disposed between the lower electrode 20 and the selection element layer 30. The barrier metal layer may include at least one of titanium nitride (TiN), tantalum nitride (TaN), or tungsten nitride (WN).

The variable resistance element layer 60 may include at least one of a magneto-resistive element layer, a phase-change resistive element layer, a channel resistive element layer, a ferro-electric element layer, or a polymer resistive element layer.

The upper electrode 70 may be disposed on the variable resistance element layer 60 to have a pillar shape or a pad shape. The upper electrode 70 may provide a current passing through the variable resistance element layer 60 to the upper line 80. For example, the top electrode 70 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or a combination thereof.

In some implementations, the upper line 80 may correspond to a bit line. In another embodiment, the upper line 80 may correspond to a word line. The upper line 80 may include a conductor such as a metal or a metal compound. For example, the upper line 80 may include a metal such as tungsten (W), one of metal compounds such as titanium (Ti) and titanium nitride (TiN), or a combination thereof.

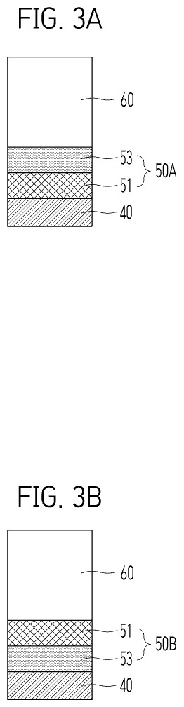

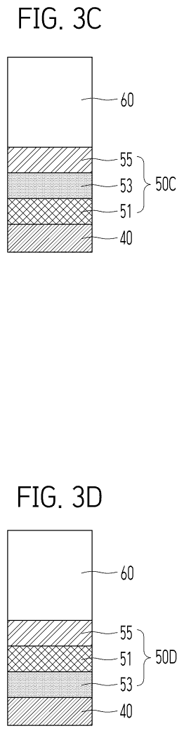

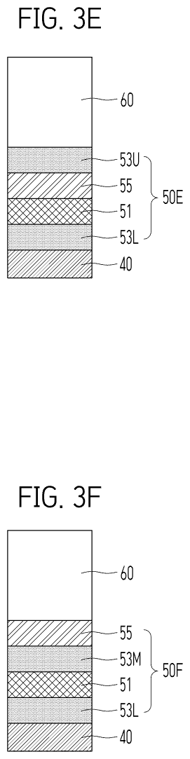

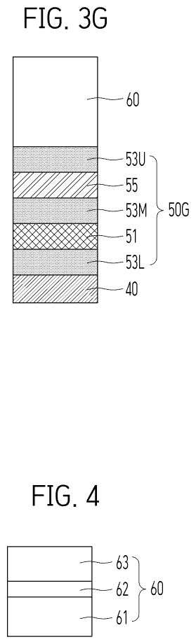

FIGS. 3A to 3G are longitudinal cross-sectional views schematically illustrating carbon blocking element layers 50A-50G according to embodiments of the present disclosure. The carbon blocking element layers 50A-50G may correspond to the carbon blocking element layers 50 of FIGS. 1 and 2. Referring to FIGS. 3A to 3G, memory devices according to embodiments of the present disclosure may include carbon blocking element layers 50A-50G disposed between the middle electrode 40 and the variable resistance element layer 60.

Referring to FIG. 3A, the carbon blocking element layer 50A in accordance with an embodiment may include a stacked structure of a carbon absorption layer 51 and a carbon barrier layer 53. The carbon absorbing layer 51 may be directly disposed on the middle electrode 40. The carbon barrier layer 53 may be directly disposed on the carbon absorbing layer 51. The carbon absorption layer 51 may absorb carbon atoms that diffuse or move from the middle electrode 40 to the carbon barrier layer 53 or the variable resistance element layer 60. The carbon absorption layer 51 may include a material having low Gibbs free energy, which allows to form a carbide. The carbon absorption layer 51 may include materials having a negative (−) Gibbs free energy for carbide formation per one carbon atom. For example, the carbon absorption layer 51 may include at least one of zirconium (Zr), niobium (Nb), titanium (Ti), tantalum (Ta), chromium (Cr), silicon (Si), molybdenum (Mo), tungsten (W), beryllium (Be), hafnium (Hf), aluminum (Al), or carbide materials thereof. In an embodiment, the carbon absorbing layer 51 may further include nitrogen (N). For example, the carbon absorption layer 51 may include at least one of zirconium nitride (ZrN), niobium nitride (NbN), titanium nitride (TiN), tantalum nitride (TaN), chromium nitride (CrN), silicon nitride (SiN), molybdenum nitride (Mo)N, tungsten nitride (WN), beryllium nitride (BeN), hafnium nitride (HfN), or aluminum nitride (AlN). In an embodiment, the carbon absorbing layer 51 may be or include a carbide material. For example, the carbon absorption layer 51 may include at least one of zirconium carbide (ZrC), niobium carbide (NbC), titanium carbide (TiC), tantalum carbide (TaC), chromium carbide (CrC), silicon carbide (SiC), molybdenum carbide (MoC), tungsten carbide (WC), beryllium carbide (BeC), hafnium carbide (HfC), or aluminum carbide (AIC). In an embodiment, the carbon absorbing layer 51 may further include carbon (C) and nitrogen (N). For example, the carbon absorbing layer 51 may include at least one of zirconium carbide nitride (ZrCN), niobium carbide nitride (NbCN), titanium carbide nitride (TiCN), tantalum carbide nitride (TaCN), chromium carbide nitride (CrCN), silicon carbide nitride (SiCN), molybdenum carbide nitride (MoCN), tungsten carbide nitride (WCN), beryllium carbide nitride (BeCN), hafnium carbide nitride (HfCN), and aluminum carbide nitride (AlCN).

The carbon barrier layer 53 can interfere and block carbon atoms that diffuse and move from the middle electrode 40 passing through the carbon absorption layer 51 to the variable resistance element layer 60. For example, the carbon barrier layer 53 may include a nitride material having interstitial gaps smaller than diameters or sizes of carbon atoms, carbon oxides, or carbon clusters. The carbon barrier layer 53 may have a mesh-type combination structure. Accordingly, the carbon barrier layer 53 can interfere and block diffusion or movement of carbon atoms, carbon oxidation, or carbon clusters that are not absorbed by the carbon absorption layer 51. In an embodiment, the carbon barrier layer 53 may include at least one of titanium nitride (TiN), silicon nitride (Si₃N₄, Si₂N₂), molybdenum nitride (MON, Mo₅N₆), or tungsten nitride (WN, W₂N, and WN₂).

Referring to FIG. 3B, the carbon blocking element layer 50B in accordance with an embodiment may include a stacked structure of a carbon barrier layer 53 and a carbon absorption layer 51. The carbon barrier layer 53 may be directly disposed on the middle electrode 40. The carbon absorbing layer 51 may be directly disposed on the carbon barrier layer 53. The carbon barrier layer 53 may prevent carbon atoms that diffuse or move from the middle electrode 40 to the carbon absorption layer 51 and the variable resistance element layer 60. The carbon absorption layer 51 may absorb carbon atoms passing through the carbon barrier layer 53 from the middle electrode 40.

Referring to FIG. 3C, the carbon blocking element layer 50C in accordance with an embodiment of the present disclosure may include a stacked structure of a carbon absorption layer 51, a carbon barrier layer 53, and a carbon blocking layer 55. The carbon absorbing layer 51 may be directly disposed on the middle electrode 40. The carbon barrier layer 53 may be directly disposed on the carbon absorbing layer 51. The carbon blocking layer 55 may be directly disposed on the carbon barrier layer 53. The carbon blocking layer 55 may have a flat surface, and may prevent diffusion or movement of carbon atoms. For example, the carbon blocking layer 55 may include an amorphous material layer for excellent surface flatness. Accordingly, the carbon blocking layer 55 can prevent phenomena of electric field concentration, electron tunneling, and leakage current caused by surface roughness of the middle electrode 40 or variable resistance element layer 60.

In an embodiment, the carbon blocking layer 55 may include a thin insulating layer. Accordingly, electrons may tunnel the blocking layer 55.

In an embodiment, the carbon blocking layer 55 may include a metal-rich oxide layer or a dopant-doped silicon oxide layer. For example, the carbon blocking layer 55 may include at least one of aluminum oxide (AIO), titanium oxide (TiO), tantalum oxide (TaO), hafnium oxide (HfO), gadolinium oxide (GdO), scandium oxide (ScO), tungsten oxide (WO), or other metal oxides. The carbon blocking layer 55 may include multi material layers. For example, the carbon blocking layer 55 may include a lower carbon blocking layer and an upper carbon blocking layer. The lower carbon blocking layer may be a metal layer or a metal-rich oxide layer. The upper carbon blocking layer may be a metal oxide layer. A metal concentration of the metal-rich oxide layer may be higher than a metal concentration according to the Law of Definite Proportions. The carbon blocking layer 55 may have a metal concentration gradient. For example, a lower area of the carbon blocking layer 55—closer to the middle electrode 40—may have a relatively high metal concentration and a relatively low oxygen concentration, and the upper area of the carbon blocking layer 55—closer to the variable resistance element layer 60—may have a relatively low metal concentration and a relatively high oxygen concentration. In an embodiment, the carbon blocking layer 55 may be or include a dopant-doped silicon oxide layer. For example, the carbon blocking layer 55 may be a silicon oxide layer containing arsenic (As) or phosphorus (P). In an embodiment, the carbon blocking layer 55 may be or include an oxide semiconductor layer such as Indium Gallium Zinc Oxide (IGZO). Because the carbon blocking layer 55 may include carriers such as metal atoms (ions) or doped dopants, the carbon blocking layer 55 may have an electrical conductivity that allows the current to flow through the carbon blocking layer 55.

Referring to FIG. 3D, a carbon blocking element layer 50D according to an embodiment may include a stacked structure of a carbon barrier layer 53, a carbon absorption layer 51, and a carbon blocking layer 55. The carbon barrier layer 53 may be directly disposed on the middle electrode 40. The carbon absorbing layer 51 may be directly disposed on the carbon barrier layer 53. The carbon blocking layer 55 may be directly disposed on the carbon absorption layer 51.

Referring to FIG. 3E, a carbon blocking element layer 50E according to an embodiment may include a lower carbon barrier layer 53L, a carbon absorption layer 51, a carbon blocking layer 55, and an upper carbon barrier layer 53U. The lower carbon barrier layer 53L may be directly disposed on the middle electrode 40. The carbon absorbing layer 51 may be directly disposed on the lower carbon barrier layer 53L. The carbon blocking layer 55 may be directly disposed on the carbon absorption layer 51. The upper carbon barrier layer 53U may be directly disposed on the carbon blocking layer 55. The lower carbon barrier layer 53L and the upper carbon barrier layer 53U may include the same material. In an embodiment, the lower carbon barrier layer 53L and the upper carbon barrier layer 53U may include different materials from each other. The lower carbon barrier layer 53L and the upper carbon barrier layer 53U can include materials, for example, titanium nitride (TiN), silicon nitride (Si₃N₄, Si₂N₂), molybdenum nitride (MON, Mo₅N₆), or tungsten nitride (WN, W₂N, and WN₂).

Referring to FIG. 3F, a carbon blocking element layer 50F according to an embodiment may include a lower carbon barrier layer 53L, a carbon absorption layer 51, a middle carbon barrier layer 53M, and a carbon blocking layer 55. The lower carbon barrier layer 53L may be directly disposed on the middle carbon electrode 40. The carbon absorbing layer 51 may be directly disposed on the lower carbon barrier layer 53L. The middle carbon barrier layer 53M may be directly disposed on the carbon absorbing layer 51. The carbon blocking layer 55 may be directly disposed on the middle carbon barrier layer 53M. The lower carbon barrier layer 53U and the middle carbon barrier layer 53M may include the same material. In an embodiment, the lower carbon barrier layer 53U and the middle carbon barrier layer 53M may include different materials from each other. The lower carbon barrier layer 53U and the middle carbon barrier layer 53M can include materials, for example, titanium nitride (TiN), silicon nitride (Si₃N₄, Si₂N₂), molybdenum nitride (MON, Mo₅N₆), or tungsten nitride (WN, W₂N, and WN₂).

Referring to FIG. 3G, a carbon blocking element layer 50G according to an embodiment may include a lower carbon barrier layer 53L, a carbon absorption layer 51, a middle carbon barrier layer 53M, a carbon blocking layer 55, and an upper carbon barrier layer 53U. The lower carbon barrier layer 53L may be directly disposed on the middle electrode 40. The carbon absorbing layer 51 may be directly disposed on the lower carbon barrier layer 53L. The middle carbon barrier layer 53M may be directly disposed on the carbon absorbing layer 51. The carbon blocking layer 55 may be directly disposed on the middle carbon barrier layer 53M. The upper carbon barrier layer 53U may be directly disposed on the carbon blocking layer 55.

The carbon blocking element layers 50A-50G may block carbon atoms that diffuse or move from the middle electrode 40 to the variable resistance element layer 60.

When carbon atoms permeate into the variable resistance element layer 60, the magnetization ability of the magnetic layers 61 and 63 may be deteriorated, the lowest resistance value Rmin of the variable resistance element layer 60 may increase, and a magnetization ratio may be reduced. Therefore, according to the implementations of the disclosed technology, because the carbon blocking layer 50 can block the diffusion or movement of carbon atoms, data preservation ability and data development ability of the variable resistance element layer 60 can be improved.

FIG. 4 is a diagram illustrating a variable resistance element layer 60 according to an embodiment of the present disclosure. The variable resistance element layer 60 may include a magneto-resistive element layer. The variable resistance element layer 60 may include a lower magnetic layer 61, a tunneling barrier layer 62, and an upper magnetic layer 63.

The lower magnetic layer 61 may include a fixed (pinned) magnetization layer. The lower magnetic layer 61 may have a single layer structure or a multilayer structure including a ferromagnetic material. The lower magnetic layer 61 may include an alloy or a compound including at least two of iron (Fe), nickel (Ni), cobalt (Co), boron (B), platinum (Pt), or palladium (Pd). For example, the lower magnetic layer 61 may include at least one of a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Co—Fe—B alloy, a Co/Pt stack, or a Co/Pd stack.

The tunneling barrier layer 62 may be disposed between the lower magnetic layer 61 and the upper magnetic layer 63. Electrons may tunnel the tunneling barrier layer 62 by an electric field of the lower electrodes 40 and the upper electrodes 70. The tunneling barrier layer 62 may include an insulating metal oxide. For example, the tunneling barrier layer 62 may include at least one of magnesium oxide (MgO), calcium oxide (CaO), strontium oxide (SrO), titanium oxide (TiO), vanadium oxide (VO), niobium oxide (NbO), aluminum oxide (Al₂O₃), titanium oxide (TiO₂), tantalum oxide (Ta₂O₅), ruthenium oxide (RuO₂), or beryllium oxide (B₂O₃).

The upper magnetic layer 63 may include a free magnetization layer. Thus, a magnetization direction of the upper magnetic layer 63 may be changed by current. The upper magnetic layer 63 may have a single layer structure or a multilayer structure including a ferromagnetic material. The upper magnetic layer 63 may include an alloy or a compound including at least two of iron (Fe), nickel (Ni), cobalt (Co), boron (B), platinum (Pt), or palladium (Pd). For example, the upper magnetic layer 63 may include at least one of a Fe—Pt alloy, a Fe—Pd alloy, a Co—Pd alloy, a Co—Pt alloy, a Fe—Ni—Pt alloy, a Co—Fe—Pt alloy, a Co—Fe—B alloy, a Co/Pt stack, or a Co/Pd stack.

In an embodiment, the memory cell MC may further include a spacer layer, a magnetization correction layer, and/or a capping layer disposed between the variable resistance element layer 60 and the upper electrode 70. The spacer layer and the capping layer may include a metal layer having excellent etching resistance, such as ruthenium (Ru). The magnetization correction layer may include a ferro-magnetic material.

In another embodiment, the lower magnetic layer 61 may be a free magnetization layer, and the upper magnetic layer 63 may be the fixed (pinned) magnetization layer. Thus, positions of the lower magnetic layer 61 and the upper magnetic layer 63 may be exchanged with each other.

According to the embodiments of the present disclosure, the carbon blocking element layer of the semiconductor memory device can block carbon atoms that diffuse or move from the middle electrode containing carbon to the variable resistance element layer.

According to the embodiments of the present disclosure, in the semiconductor memory device having the carbon electrode, the magnetization ability of the magnetic layers can be prevented from deteriorating. The minimum resistance value of the variable resistance element layer can be prevented from increasing. A decrease of magnetization of the variable resistance element layer including the magnetic layers can be prevented.

According to embodiments of the present disclosure, data retention and data development capabilities of the variable resistance element layer can be improved.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A semiconductor device comprising:
a lower electrode;
a selection element layer over the lower electrode;
a middle electrode over the selection element layer;
a carbon blocking element layer over the middle electrode;
a variable resistance element layer over the carbon blocking element layer; and
an upper electrode over the variable resistance element layer,
wherein the carbon blocking element layer includes a carbon absorption layer configured to absorb carbon atoms and a carbon barrier layer configured to block a diffusion of the carbon atoms.

2. The semiconductor device of claim 1,
wherein the selection element layer includes at least one of Metal Insulator Transition (MIT) materials, Mixed Ion-Electron Conducting (MIEC) materials, Ovonic Threshold Switching (OTS) materials containing a chalcogenide material, or a dopant-doped insulating layer.

3. The semiconductor device of claim 1,
wherein the middle electrode includes a carbon layer.

4. The semiconductor device of claim 1,
wherein the variable resistance element layer includes a lower magnetic layer, a tunneling barrier layer over the lower magnetic layer, and an upper magnetic layer over the tunneling barrier layer.

5. The semiconductor device of claim 1,
wherein the carbon absorption layer includes a material having negative Gibbs free energy for being formed into a carbide material.

6. The semiconductor device of claim 1,
wherein the carbon absorption layer includes at least one of zirconium, niobium, titanium, tantalum, chromium, silicon, molybdenum, tungsten, beryllium, hafnium, aluminum, or carbides thereof.

7. The semiconductor device of claim 1,
wherein the carbon barrier layer includes a compound having a lattice gap smaller than a size of a carbon oxide and a size of carbon clusters.

8. The semiconductor device of claim 1,
wherein the carbon barrier layer includes at least one of titanium nitride, silicon nitride, molybdenum nitride, or tungsten nitride.

9. The semiconductor device of claim 1,
wherein the carbon blocking element layer further includes a carbon blocking layer over the carbon barrier layer configured to block the diffusion of the carbon atoms, and
wherein the carbon blocking layer includes at least one of a metal-rich oxide layer or a dopant-doped silicon oxide layer.

10. The semiconductor device of claim 9,
wherein the carbon blocking layer includes at least one of aluminum oxide, titanium oxide, tantalum oxide, hafnium oxide, gadolinium oxide, scandium oxide, tungsten oxide, or other metal oxides.

11. The semiconductor device of claim 9,
wherein the carbon barrier layer includes a first carbon barrier layer and a second carbon barrier layer,
wherein:
the first carbon barrier layer is over the middle electrode,
a carbon absorbing layer is over the first carbon barrier layer,
the second carbon barrier layer is over the carbon absorbing layer, and
the carbon blocking layer is over the second carbon barrier layer.

12. The semiconductor device of claim 11,
wherein the carbon barrier layer further includes a third carbon barrier layer over the carbon blocking layer.

13. The semiconductor device of claim 1, further comprising:
a lower interconnection under the lower electrode and structured to extend in a first horizontal direction; and
an upper interconnection over the upper electrode and structured to extend in a second horizontal direction perpendicular to the first horizontal direction.

14. A semiconductor device comprising:
a lower interconnection;
a lower electrode over the lower interconnection;
a selection element layer over the lower electrode;
a carbon layer over the selection element layer;
a carbon diffusion blocking element layer over the carbon layer;
a variable resistance element layer over the carbon diffusion blocking element layer;
an upper electrode over variable resistance element layer; and
an upper interconnection over the upper electrode,
wherein the carbon diffusion blocking element layer includes:
a carbon absorption layer;
a carbon diffusion barrier layer and a carbon diffusion blocking layer that include materials different from each other.

15. The semiconductor device of claim 14,
wherein the carbon absorption layer includes at least one of zirconium, niobium, titanium, tantalum, chromium, silicon, molybdenum, tungsten, beryllium, hafnium, aluminum, or carbides thereof.

16. The semiconductor device of claim 14,
wherein the carbon diffusion barrier layer includes at least one of titanium nitride, silicon nitride, molybdenum nitride, or tungsten nitride.

17. The semiconductor device of claim 14,
wherein the carbon diffusion blocking layer includes at least one of aluminum oxide, titanium oxide, tantalum oxide, hafnium oxide, gadolinium oxide, scandium oxide, tungsten oxide, or other metal oxides.

18. The semiconductor device of claim 14,
wherein the carbon diffusion barrier layer includes:
a first carbon diffusion barrier layer between the carbon layer and the carbon absorption layer; and
a second carbon layer between the carbon absorption layer and the carbon diffusion blocking layer.

19. The semiconductor device of claim 18,
wherein the carbon diffusion barrier layer further includes a third carbon diffusion barrier layer between the carbon diffusion blocking layer and the variable resistance element layer.

20. The semiconductor device of claim 14,
wherein the variable resistance element layer includes a lower magnetic layer, a tunneling barrier layer over the lower magnetic layer, and an upper magnetic layer over the tunneling barrier layer.
